(19) United States
(12) Patent Application Publication
(10) Pub. No.: US 2019/0146292 A1
(43) Pub. Date: May 16, 2019

(54) DISPLAY DEVICE

(71) Applicant: Samsung Display Co. Ltd., Yongin-si (KR)

(72) Inventor: Hwa Sung WOO, Asan-si (KR)

(21) Appl. No.: 15/980,366

(22) Filed: May 15, 2018

(30) Foreign Application Priority Data
Nov. 16, 2017 (KR) 10-2017-0153115

(51) Int. Cl. G02F 1/1362; G02F 1/1343; G09G 3/36; H01L 27/12

(52) U.S. Cl. CPC G02F 1/136286; G02F 1/134309; G02F 2001/134345; H01L 27/1218; H01L 27/124; G09G 3/3696

(57) ABSTRACT

A display device includes a gate line, a data line, a voltage division reference line, two subpixel electrodes, and three transistors (each including a gate connected to the gate line). The first transistor includes a first source (connected to the data line) and a first drain. The second transistor includes a second source (connected to the data line) and a second drain. The second drain extends in a direction. The third transistor includes a semiconductor member, a third source (connected to the voltage division reference line), and a third drain (connected to the second drain). The first subpixel electrode and the second subpixel electrode are respectively connected to the first drain and the second drain. The maximum overlap length of the third drain and the semiconductor member in the direction is unequal to the maximum overlap length of the third source and the semiconductor member in the direction.

### CROSS-REFERENCE TO RELATED APPLICATION

This application claims priority to Korean Patent Application No. 10-2017-0153115 filed on Nov. 16, 2017 in the Korean Intellectual Property Office; the disclosure of the Korean Patent Application is incorporated herein by reference in its entirety.

### BACKGROUND

### 1. Field

The technical field relates to a display device.

### 2. Description of the Related Art

A display device, such as a liquid crystal display (LCD) device, may include electric field generator electrodes (such as a pixel electrode and a common electrode) and a liquid crystal layer. The display device may display an image by applying a voltage to the electric field generator electrode for determining orientations of liquid crystal molecules of the liquid crystal layer to control transmission of incident light.

### SUMMARY

An embodiment may be related to a display device that includes pixels each having two subpixels. A method of operating the display device may include providing different voltages to the two subpixels.

A voltage ratio between two subpixels in each pixel may affect display quality of a display device. In an embodiment, to attain uniform display quality, a constant voltage ratio between subpixels is configured for pixels in a display device.

An embodiment may be related to a display device having uniform display quality.

It should be noted that objects of the present disclosure are not limited to the above-described objects, and other objects of the present disclosure will be apparent to those skilled in the art from the following descriptions.

An embodiment may be related a display device. The display device includes a base substrate; a gate line located on the base substrate, a first data line insulated from the gate line and intersecting with the gate line, and a voltage division reference line spaced apart from the gate line and the first data line; a first switching element which comprises a first gate electrode located on the base substrate and electrically connected to the gate line, a first semiconductor member located on the first gate electrode, a first source electrode which is electrically connected to the first data line and overlaps with the first semiconductor member, and a first drain electrode which overlaps with the first semiconductor member and is spaced apart from the first source electrode; a second switching element which comprises a second gate electrode located on the base substrate and electrically connected to the gate line, a second semiconductor member located on the second gate electrode, a second source electrode which is electrically connected to the first data line and overlaps with the second semiconductor member, and a second drain electrode which overlaps with the second semiconductor member and extends outward from the second semiconductor member in one direction; a third switching element which comprises a third gate electrode located on the base substrate and electrically connected to the gate line, a third semiconductor member located on the third gate electrode, a third source electrode which is electrically connected to the voltage division reference line and overlaps with the third semiconductor member, and a third drain electrode which overlaps with the third semiconductor member and is connected to the second drain electrode; a first subpixel electrode electrically connected to the first drain electrode; and a second subpixel electrode electrically connected to the second drain electrode, wherein any one of the third drain electrode and the third source electrode extends outward from the third semiconductor member in the one direction, and wherein a first overlap width between the third drain electrode and the third semiconductor member, which is measured in the one direction, is different from a second overlap width between the third source electrode and the third semiconductor member, which is measured in the one direction.

An embodiment may be related a display device. The display device includes a base substrate; a gate line which is located on the base substrate and extends in a first direction, a data line which is insulated from the gate line and extends in a second direction which intersects with the first direction, and a voltage division reference line insulated from the gate line and the data line; a first switching element which comprises a first gate electrode located on the base substrate and electrically connected to the gate line, a first semiconductor member located on the first gate electrode, a first source electrode which is electrically connected to the data line and overlaps with the first semiconductor member, and a first drain electrode which overlaps with the first semiconductor member and is spaced apart from the first source electrode; a second switching element which comprises a second gate electrode located on the base substrate and electrically connected to the gate line, a second semiconductor member located on the second gate electrode, a second source electrode which is electrically connected to the data line and overlaps with the second semiconductor member, and a second drain electrode which overlaps with the second semiconductor member and extends outward from the second semiconductor member in the second direction; a third switching element which comprises a third gate electrode located on the base substrate and electrically connected to the gate line, a third semiconductor member located on the third gate electrode, a third source electrode which is electrically connected to the voltage division reference line and overlaps with the third semiconductor member, and a third drain electrode which overlaps with the third semiconductor member, is electrically connected to the second drain electrode, and extends outward from the third semiconductor member in the second direction; a first subpixel electrode electrically connected to the first drain electrode; and a second subpixel electrode electrically connected to the second drain electrode, wherein a side surface of the third semiconductor member is in contact with the third drain electrode, and an end of the third drain electrode overlaps with the third semiconductor member and is located inside an edge of the third semiconductor member.

An embodiment may be related a display device. The display device includes a base substrate; a gate line which is located on the base substrate and extends in a first direction, a data line which is insulated from the gate line and extends in a second direction which intersects with the first direction, and a voltage division reference line insulated from the gate line and the data line; a first switching element which comprises a first gate electrode located on the base substrate and electrically connected to the gate line, a first semiconductor member located on the first gate electrode, a first source electrode which is electrically connected to the data line and overlaps with the first semiconductor member, and a first drain electrode which overlaps with the first semiconductor member and is spaced apart from the first source electrode; a second switching element which comprises a second gate electrode located on the base substrate and electrically connected to the gate line, a second semiconductor member located on the second gate electrode, a second source electrode which is electrically connected to the data line and overlaps with the second semiconductor member, and a second drain electrode which overlaps with the second semiconductor member and extends outward from the second semiconductor member in the second direction; a third switching element which comprises a third gate electrode located on the base substrate and electrically connected to the gate line, a third semiconductor member located on the third gate electrode, a third source electrode which is electrically connected to the voltage division reference line, overlaps with the third semiconductor member, and extends outward from the third semiconductor member in the second direction, and a third drain electrode which overlaps with the third semiconductor member and is electrically connected to the second drain electrode; a first subpixel electrode electrically connected to the first drain electrode; and a second subpixel electrode electrically connected to the second drain electrode, wherein a side surface of the third semiconductor member is in contact with the third source electrode, and an end of the third source electrode overlaps with the third semiconductor member and is located inside an edge of the third semiconductor member.

An embodiment may be related to a display device. The display device may include a base substrate, a gate line, a first data line, a voltage division reference line, a first switching element, a second switching element, a third switching element, a first subpixel electrode, and a second subpixel electrode. The gate line may be located on the base substrate. The first data line may be electrically insulated from the gate line and intersects the gate line. The voltage division reference line may be electrically insulated from each of the gate line and the first data line. The first switching element may include a first gate electrode electrically connected to the gate line, a first semiconductor member overlapping the first gate electrode, a first source electrode electrically connected to the first data line and overlapping the first semiconductor member, and a first drain electrode overlapping the first semiconductor member and spaced from the first source electrode. The second switching element may include a second gate electrode electrically connected to the gate line, a second semiconductor member overlapping the second gate electrode, a second source electrode electrically connected to the first data line and overlapping the second semiconductor member, and a second drain electrode overlapping the second semiconductor member and extending beyond the second semiconductor member in a first direction. The third switching element may include a third gate electrode electrically connected to the gate line, a third semiconductor member overlapping the third gate electrode, a third source electrode electrically connected to the voltage division reference line and overlapping the third semiconductor member, and a third drain electrode overlapping the third semiconductor member and electrically connected to the second drain electrode. The first subpixel electrode may be electrically connected to the first drain electrode. The second subpixel electrode may be electrically connected to the second drain electrode. A first overlap width may be in the first direction and may be a width of a maximum portion of the third drain electrode positioned within a perimeter of the third semiconductor member in a plan view of the display device. The first overlap width may be the maximum overlap length (i.e., the length of maximum overlap) of the third drain electrode and the third semiconductor member in the first direction. A second overlap width may be in the first direction and may be a width of a maximum portion of the third source electrode positioned within the perimeter of the third semiconductor member in the plan view of the display device. The second overlap width may be the maximum overlap length (i.e., the length of maximum overlap) of the third source electrode and the third semiconductor member in the first direction. The first overlap width may be unequal to the second overlap width.

The second subpixel electrode may be spaced from the second semiconductor member in the first direction in the plan view of the display device.

A width of the third semiconductor member in the first direction may be greater than the first overlap width and substantially equal to the second overlap width.

A width of the third semiconductor member in the first direction may be greater than the second overlap width and substantially equal to the first overlap width.

A width of the third semiconductor member in the first direction may be greater than each of the first overlap width and the second overlap width.

A side of the third semiconductor member may directly contact each of the third source electrode and the third drain electrode.

At least one of an end of the third source electrode and an end of the third drain electrode may be located inside the perimeter of the third semiconductor member in the plan view of the display device.

A portion of the voltage division reference line may extend in the first direction and may overlap both the first subpixel electrode and the second subpixel electrode.

The voltage division reference line and the first data line directly contact a same side of a same component and may include a same material.

The display device may include a gate insulting layer located between the first data line and the gate line. The first data line may directly contact the gate insulating layer.

The first data line may extend in the first direction and may overlap both the first subpixel electrode and the second subpixel electrode.

Two edges of the first data line may be positioned between two edges of the first subpixel electrode in the plan view of the display device.

The display device may include a second data line which may extend in the first direction and may overlap both the first subpixel electrode and the second subpixel electrode. Two edges of the second data line may be positioned between the two edges of the first subpixel electrode in the plan view of the display device.

The display device may include a first maintenance line. A first portion of the first maintenance line may extend parallel to the gate line. A second portion of the first maintenance line may extend from the first portion and may extend parallel to the first data line. A third portion of the first maintenance line may extend from the first portion and may extend parallel to the first data line. A component of the display device may directly contact the first maintenance line without directly contacting the voltage division reference line. The first data line may overlap the first subpixel electrode. The first subpixel electrode may be positioned between the second portion of the first maintenance line and the third portion of the first maintenance line in the plan view of the display device.

The first maintenance line and the gate line directly contact a same side of a same component and may include a same material.

The display device may include a first shielding electrode and a second shielding electrode. The first shielding electrode may overlap the second portion of the first maintenance line. The second shielding electrode may overlap the third portion of the first maintenance line. Both the first subpixel electrode and the second subpixel electrode may be positioned between the first shielding electrode and the second shielding electrode in the plan view of the display device. The first shielding electrode, the second shielding electrode, and the first subpixel electrode directly contact a same side of a same component and may include a same material.

The display device may include a second maintenance line spaced from the first maintenance line. A first portion of the second maintenance line may extend parallel to the gate line. A second portion of the second maintenance line may extend parallel to the first data line and may be directly connected to the first portion of the second maintenance line. A third portion of the second maintenance line may extend parallel to the first data line and may be directly connected to the first portion of the second maintenance line. The second maintenance line and the first maintenance line directly contact a same side of a same layer. The second subpixel electrode may be positioned between the second portion of the second maintenance line and the third portion of the second maintenance line in the plan view of the display device.

The second portion of the second maintenance line may overlap the first shielding electrode. The third portion of the second maintenance line may overlap the second shielding electrode.

An embodiment may be related to a display device. The display device may include the following elements: a base substrate; a gate line which may be located on the base substrate and may extend in a first direction; a data line which may be electrically insulated from the gate line and may extend in a second direction different from the first direction; a voltage division reference line electrically insulated from each of the gate line and the data line; a first switching element which comprises a first gate electrode electrically connected to the gate line, a first semiconductor member overlapping the first gate electrode, a first source electrode electrically connected to the data line and overlapping the first semiconductor member, and a first drain electrode overlapping the first semiconductor member and spaced from the first source electrode; a second switching element which comprises a second gate electrode electrically connected to the gate line, a second semiconductor member overlapping the second gate electrode, a second source electrode electrically connected to the data line and overlapping the second semiconductor member, and a second drain electrode overlapping the second semiconductor member and extending beyond the second semiconductor member in the second direction; a third switching element which comprises a third gate electrode electrically connected to the gate line, a third semiconductor member overlapping the third gate electrode, a third source electrode electrically connected to the voltage division reference line and overlapping the third semiconductor member, and a third drain electrode overlapping the third semiconductor member, electrically connected to the second drain electrode, and extending beyond the third semiconductor member in the second direction; a first subpixel electrode electrically connected to the first drain electrode; and a second subpixel electrode electrically connected to the second drain electrode. A side of the third semiconductor member may directly contact the third drain electrode. An end of the third drain electrode may overlap the third semiconductor member and may be located inside a perimeter of the third semiconductor member in a plan view of the display device.

An embodiment may be related to a display device. The display device may include the following elements: a base substrate; a gate line which may be located on the base substrate and may extend in a first direction; a data line which may be electrically insulated from the gate line and may extend in a second direction different from the first direction; a voltage division reference line electrically insulated from each of the gate line and the data line; a first switching element which comprises a first gate electrode electrically connected to the gate line, a first semiconductor member overlapping the first gate electrode, a first source electrode electrically connected to the data line and overlapping the first semiconductor member, and a first drain electrode overlapping the first semiconductor member and spaced from the first source electrode; a second switching element which comprises a second gate electrode electrically connected to the gate line, a second semiconductor member overlapping the second gate electrode, a second source electrode electrically connected to the data line and overlapping the second semiconductor member, and a second drain electrode overlapping the second semiconductor member and extending beyond the second semiconductor member in the second direction; a third switching element which comprises a third gate electrode electrically connected to the gate line, a third semiconductor member overlapping the third gate electrode, a third source electrode electrically connected to the voltage division reference line, overlapping the third semiconductor member, and extending beyond the third semiconductor member in the second direction, and a third drain electrode overlapping the third semiconductor member and electrically connected to the second drain electrode; a first subpixel electrode electrically connected to the first drain electrode; and a second subpixel electrode electrically connected to the second drain electrode. A side of the third semiconductor member may directly contact the third source electrode. An end of the third source electrode may overlap the third semiconductor member and may be located inside a perimeter of the third semiconductor member in a plan view of the display device.

### BRIEF DESCRIPTION OF THE DRAWINGS

FIG. 1 is a circuit diagram of one pixel of a display device according to one embodiment.

FIG. 2 is a layout view (or plan view) of one pixel of a display device according to one embodiment.

FIG. 3 is a cross-sectional view taken along X1-X1′ of FIG. 2 according to one embodiment.

FIG. 4 is a cross-sectional view taken along X3-X3′ of FIG. 2 according to one embodiment.

FIG. 5 is a cross-sectional view taken along X5-X5′ of FIG. 2 according to one embodiment.

FIG. 6 is an enlarged view of part Q1 of FIG. 2, which illustrates structures of a first semiconductor member, a first source electrode, a first drain electrode, a second semiconductor member, a second source electrode, a second drain electrode, a third semiconductor member, a third source electrode, and a third drain electrode according to one embodiment.

FIG. 7 is an enlarged view of part Q1 of FIG. 2 according to one embodiment.

FIG. 8 is a layout view (or plan view) of one pixel of a display device according to one embodiment.

FIG. 9 is an enlarged view of part Q2 of FIG. 8, which illustrates structures of a first semiconductor member, a first source electrode, a first drain electrode, a second semiconductor member, a second source electrode, a second drain electrode, a third semiconductor member, a third source electrode, and a third drain electrode according to one embodiment.

FIG. 10 is a layout view (or plan view) of one pixel of a display device according to one embodiment.

FIG. 11 is an enlarged view of part Q3 of FIG. 10, which illustrates structures of a first semiconductor member, a first source electrode, a first drain electrode, a second semiconductor member, a second source electrode, a second drain electrode, a third semiconductor member, a third source electrode, and a third drain electrode according to one embodiment.

FIG. 12 is a layout view (or plan view) of one pixel of a display device according to one embodiment.

FIG. 13 is an enlarged view of part Q4 of FIG. 12, which illustrates structures of a first semiconductor member, a first source electrode, a first drain electrode, a second semiconductor member, a second source electrode, a second drain electrode, a third semiconductor member, a third source electrode, and a third drain electrode according to one embodiment.

### DETAILED DESCRIPTION OF EMBODIMENTS

Example embodiments are described with reference to the accompanying drawings. The example embodiments may be embodied in many different forms and should not be construed as being limited. Like reference numerals may refer to like elements in the description.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

When a first element is referred to as being “on”, “connected to” or “coupled to” a second element or layer, the first element can be directly on, connected or coupled to the second element, or one or more intervening elements may be present between the first element and the second element. In contrast, when a first element is referred to as being “directly on”, “directly connected to” or “directly coupled to” a second element or layer, there are no intended intervening elements (except environmental elements such as air) present between the first element and the second element. The term “and/or” may include any and all combinations of one or more of the associated items.

The term “connect” may mean “electrically connect.” The term “insulate” may mean “electrically insulate” or “electrically isolate.” The term “contact” may mean “direct contact” or “directly contact.” The term “overlap with” may mean “overlap.” The term “width” may mean “dimension,” “span,” or “length.” The term “edge” may mean “perimeter” or “boundary.” The term “end” may mean “edge” or “side.” The term “which” may mean “that.” The term “different from” may mean “unequal to.”

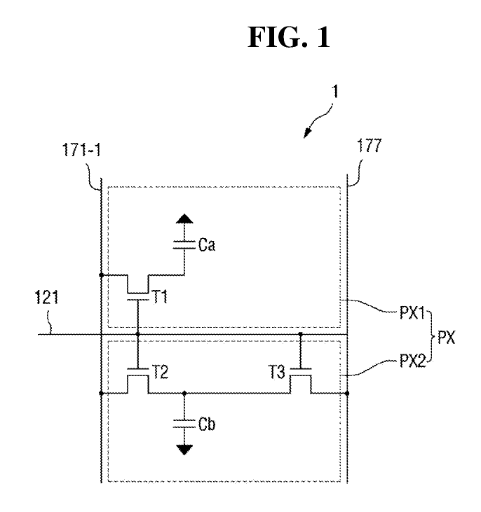

FIG. 1 is a circuit diagram of one pixel of a display device according to one embodiment. Referring to FIG. 1, a display device 1 includes a gate line 121 for transmitting a gate signal, a first data line 171-1 for transmitting a data voltage, a voltage division reference line 177 to which a certain voltage may be applied, and a pixel PX connected to the gate line 121, the first data line 171-1, and the voltage division reference line 177.

The pixel PX includes a first subpixel PX1 and a second subpixel PX2.

The first subpixel PX1 includes a first switching element T1 and a first liquid crystal capacitor Ca connected to the first switching element T1. The second subpixel PX2 includes a second switching element T2, a second liquid crystal capacitor Cb connected to the second switching element T2, and a third switching element T3.

The first switching element T1, the second switching element T2, and the third switching element T3 may be thin film transistors which are three-terminal elements.

A first terminal of the first switching element T1 may be connected to the gate line 121, a second terminal of the first switching element T1 may be connected to the first data line 171-1, and a third terminal of the first switching element T1 may be connected to the first liquid crystal capacitor Ca. Particularly, the third terminal of the first switching element T1 may be connected to a first subpixel electrode which forms the first liquid crystal capacitor Ca.

A first terminal of the second switching element T2 may be connected to the gate line 121, a second terminal of the second switching element T2 may be connected to the first data line 171-1, and a third terminal of the second switching element T2 may be connected to the second liquid crystal capacitor Cb. Particularly, the third terminal of the second switching element T2 may be connected to a second subpixel electrode which forms the second liquid crystal capacitor Cb.

A first terminal of the third switching element T3 may be connected to the gate line 121, a second terminal of the third switching element T3 may be connected to the voltage division reference line 177, and a third terminal of the third switching element T3 may be connected to the third terminal of the second switching element T2. A reference voltage for voltage division may be applied to the second terminal of the third switching element T3 through the voltage division reference line 177.

In operations of the display device 1 according to one embodiment, when a gate-ON voltage is applied to the gate line 121, the first switching element T1, the second switching element T2, and the third switching element T3, connected thereto, are all turned on and the first liquid crystal capacitor Ca and the second liquid crystal capacitor Cb are charged by a data voltage transmitted through the first data line 171-1. Here, the same data voltage is applied to the first subpixel electrode and the second subpixel electrode and the first liquid crystal capacitor Ca and the second liquid crystal capacitor Cb are charged with the same value as a difference between a common voltage and the data voltage.

Since the third switching element T3 is in a turned-on state, the data voltage transmitted to the second subpixel PX2 through the first data line 171-1 is divided through the third switching element T3 connected to the second switching element T2 in series. In an embodiment, division of voltage is performed depending on a size of a channel between the second switching element T2 and the third switching element T3. Accordingly, even when the same data voltage is transmitted to the first subpixel PX1 and the second subpixel PX2 through the first data line 171-1, voltages with which the first liquid crystal capacitor Ca and the second liquid crystal capacitor Cb are charged are different from each other. That is, the voltage with which the second liquid crystal capacitor Cb is charged becomes lower than the voltage which charges the first liquid crystal capacitor Ca.

Due to this, the voltages with which the first liquid crystal capacitor Ca and the second liquid crystal capacitor Cb in one pixel PX are charged may be different from each other such that side visibility may be improved. A level of constant voltage applied to the second terminal of the third switching element T3 may be higher than a level of the common voltage applied to a common electrode. For example, when the common voltage is about 7 V, the constant voltage applied to the second terminal of the third switching element T3 may be about 8 V to 11 V but is not limited thereto.

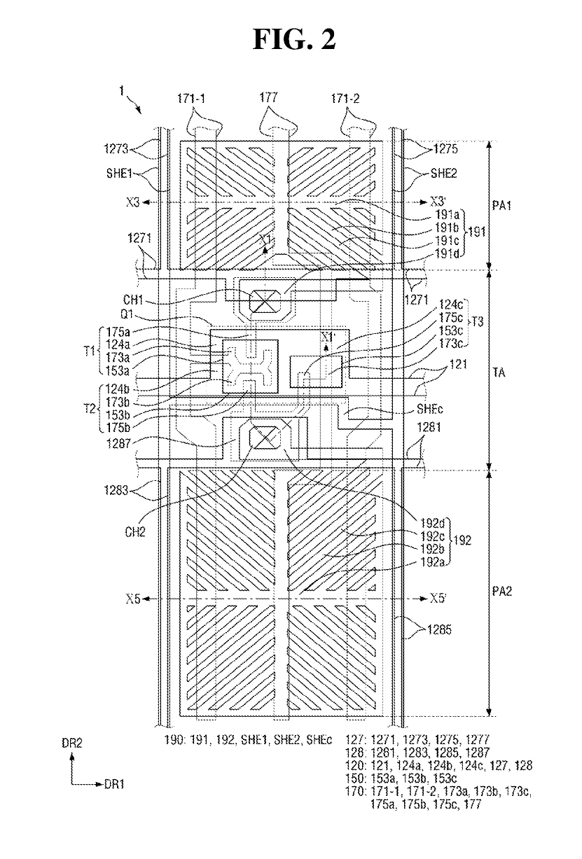

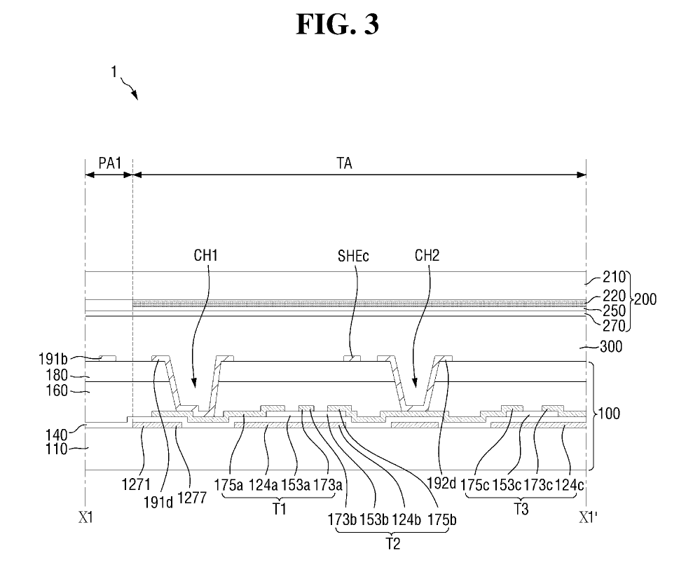

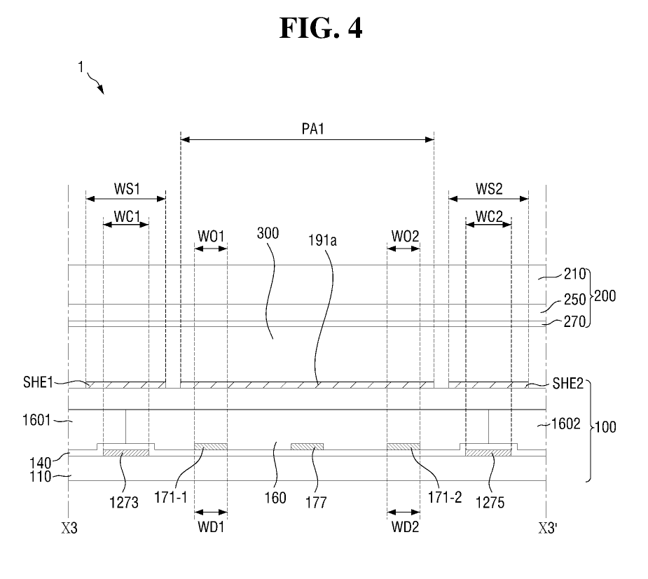

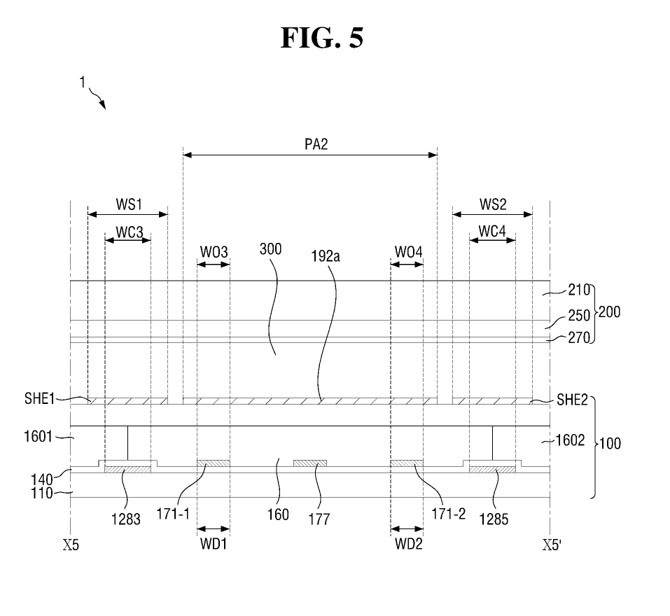

FIG. 2 is a layout view of one pixel of the display device according to one embodiment, FIG. 3 is a cross-sectional view taken along X1-X1′ of FIG. 2, FIG. 4 is a cross-sectional view taken along X3-X3′ of FIG. 2, and FIG. 5 is a cross-sectional view taken along X5-X5′ of FIG. 2.

Referring to FIGS. 2 to 5, the display device 1 according to one embodiment may include a first substrate 100, a second substrate 200 which faces the first substrate 100, and a liquid crystal layer 300 located between the first substrate 100 and the second substrate 200.

The first substrate 100 may be a thin film transistor array substrate on which switching elements for driving liquid crystal molecules, for example, thin film transistors are formed, and the second substrate 200 may be a substrate which faces the first substrate 100.

The liquid crystal layer 300 may include a plurality of liquid crystal molecules having dielectric anisotropy. When an electric field is applied to between the first substrate 100 and the second substrate 200, liquid crystal molecules rotate in a particular direction between the first substrate 100 and the second substrate 200 such that light may be transmitted or blocked out. In an embodiment, the term rotation may include not only actual rotation of the liquid crystal molecules but also a change in array of the liquid crystal molecules due to the electric field.

The first substrate 100 may have the following structures.

A first base substrate 110 may include an insulating material such as glass, quartz, polymer resin, and the like. The polymer material of the polymer resin may include at least one of polyethersulfone (PES), polyacrylate (PA), polyarylate (PAR), polyetherimide (PEI), polyethylene naphthalate (PEN), polyethylene terephthalate PET), polyphenylene sulfide (PPS), polyallylate, polyimide (PI), polycarbonate (PC), cellulose triacetate (CAT), and cellulose acetate propionate (CAP).

The first base substrate 110 may be a rigid substrate or a flexible substrate capable of being bent, folded, rolled, and the like. The flexible substrate may include, for example, PI.

A first subpixel area PA1, a second subpixel area PA2, and a switching element area TA may be defined on the first base substrate 110. The first subpixel area PA1 may be defined as an area in which a first stem electrode 191a and a first branch electrode 191b of a first subpixel electrode 191 are arranged. The second subpixel area PA2 may be defined as an area in which a second stem electrode 192a and a second branch electrode 192b of a second subpixel electrode 192 are arranged. In an embodiment, the switching element area TA may be defined as an area in which the first switching element T1, the second switching element T2, the third switching element T3, and the like are arranged. In some embodiments, the switching element area TA may be located between the first subpixel area PA1 and the second subpixel area PA2.

A first conductive layer 120 may be located on the first base substrate 110. The first conductive layer 120 may include the gate line 121, a first gate electrode 124a, a second gate electrode 124b, and a third gate electrode 124c. The gate line 121, the first gate electrode 124a, the second gate electrode 124b, and the third gate electrode 124c may be located on the same layer and may include the same material. In embodiments, being located on the same layer indicates that the same side of the same layer directly contacts the recited components and/or that the recited components are located on the same level.

The gate line 121 may extend in a first direction DR1.

The first gate electrode 124a, the second gate electrode 124b, and the third gate electrode 124c may be electrically connected to the gate line 121.

In some embodiments, the first gate electrode 124a, the second gate electrode 124b, and the third gate electrode 124c may be connected to the gate line 121 but are not limited thereto.

The first conductive layer 120 may include one or more of molybdenum (Mo), aluminum (Al), platinum (Pt), palladium (Pd), silver (Ag), magnesium (Mg), gold (Au), nickel (Ni), neodymium (Nd), iridium (Ir), chrome (Cr), titanium (Ti), tantalum (Ta), tungsten (W), and copper (Cu). In an embodiment, the first conductive layer 120 may have a single-layer structure or a multilayer structure.

A gate insulating layer 140 may be located on the first conductive layer 120. The gate insulating layer 140 may include an inorganic insulating material such as a silicon compound, a metal oxide, and the like. For example, the gate insulating layer 140 may include a silicon oxide, a silicon nitride, a silicon oxynitride, an aluminum oxide, a tantalum oxide, a hafnium oxide, a zirconium oxide, a titanium oxide, and the like. They may be used as a single or a combination thereof. The gate insulating layer 140 may be a single film or a multilayer film including deposition films of different materials.

A semiconductor layer 150 may be located on the gate insulating layer 140. The semiconductor layer 150 may include a first semiconductor member 153a, a second semiconductor member 153b, and a third semiconductor member 153c.

The first semiconductor member 153a may overlap the first gate electrode 124a, the second semiconductor member 153b may overlap with the second gate electrode 124b, and the third semiconductor member 153c may overlap with the third gate electrode 124c.

In some embodiments, as shown in FIG. 2, the first semiconductor member 153a and the second semiconductor member 153b may be connected to each other, and the third semiconductor member 153c may be spaced apart from the first semiconductor member 153a and the second semiconductor member 153b.

The semiconductor layer 150 may include polycrystalline silicon. The polycrystalline silicon may be formed by crystallizing amorphous silicon. The crystallization method may include, for example, one or more of a rapid thermal annealing (RTA) method, a solid phase crystallization (SPC) method, an excimer laser annealing (ELA) method, a metal induced crystallization (MIC) method, a metal induced lateral crystallization (MILC) method, a sequential lateral solidification (SLS) method, and the like. As another example, the semiconductor layer 150 may include one or more of monocrystalline silicon, low temperature polycrystalline silicon, amorphous silicon, and the like. In an embodiment, the semiconductor layer 150 may include an oxide semiconductor. In an embodiment, the semiconductor layer 150 may include one or more of a binary compound ABx, a ternary compound ABxCy, and a quaternary compound ABxCyDz, which contain indium, zinc, gallium, tin, Ti, Al, hafnium (Hf), zirconium (Zr), Mg, and the like. For example, the semiconductor layer 150 may include an indium-tin-zinc oxide (ITZO, an oxide including indium, tin, and zinc) or an indium-gallium-zinc oxide (IGZO, an oxide including indium, gallium, and zinc).

A second conductive layer 170 may be located on the gate insulating layer 140, and a part of the second conductive layer 170 may be located on the semiconductor layer 150.

In some embodiments, the second conductive layer 170 may be formed by using a mask different from that of the semiconductor layer 150. Accordingly, the part of the second conductive layer 170 may be in direct contact with the gate insulating layer 140. In an embodiment, another part of the second conductive layer 170 may be located on the semiconductor layer 150 and may be in (direct) contact with a side surface of at least one component of the semiconductor layer 150. In an embodiment, an area occupied by the second conductive layer 170 in one pixel may be larger than an area occupied by the semiconductor layer 150.

The second conductive layer 170 may include the first data line 171-1, a second data line 171-2, a first source electrode 173a, a first drain electrode 175a, a second source electrode 173b, a second drain electrode 175b, a third source electrode 173c, a third drain electrode 175c, and the voltage division reference line 177.

The first data line 171-1, the second data line 171-2, the first source electrode 173a, the first drain electrode 175a, the second source electrode 173b, the second drain electrode 175b, the third source electrode 173c, the third drain electrode 175c, and the voltage division reference line 177 may include the same material and may be located on the same layer.

The first data line 171-1 and the second data line 171-2 may generally extend in a second direction DR2 which intersects with the first direction DR1 and may be spaced apart in the first direction DR1. In some embodiments, the first data line 171-1 and the second data line 171-2 overlap with the first subpixel electrode 191 and the second subpixel electrode 192.

A constant voltage for voltage division is applied to the voltage division reference line 177. In some embodiments, a voltage applied to the voltage division reference line 177 may be different from a common voltage applied to a common electrode 270. For example, a voltage at a higher level than that of the common voltage may be provided to the voltage division reference line 177.

At least a part of the voltage division reference line 177 may be disposed parallel to the first data line 171-1 and the second data line 171-2. In some embodiments, the voltage division reference line 177 may overlap with the first subpixel electrode 191 and the second subpixel electrode 192 and may be disposed between the first data line 171-1 and the second data line 171-2 in a plane view.

Each of the first data line 171-1, the second data line 171-2, and the voltage division reference line 177 may include a part located immediately above the gate insulating layer 140 and in contact with the gate insulating layer 140.

The first source electrode 173a may be electrically connected to the first data line 171-1 and may be located on, in contact with, and overlap with the first semiconductor member 153a. In some embodiments, a part of the first source electrode 173a, located on the first semiconductor member 153a, may have a U shape.

The first drain electrode 175a may be located on the first semiconductor member 153a, in contact with the first semiconductor member 153a, and overlap with the first semiconductor member 153a. The first drain electrode 175a is spaced apart from the first source electrode 173a on the first semiconductor member 153a. The first drain electrode 175a may include a bar-shaped part which faces the first source electrode 173a and stretches generally parallel to the second direction DR2, and an extension portion opposite thereto. The bar-shaped part of the first drain electrode 175a may stretch generally parallel to the second direction DR2 from the first semiconductor member 153a toward the first subpixel area PA1. In an embodiment, the bar-shaped part of the first drain electrode 175a may extend beyond the first semiconductor member 153a.

In some embodiments, parts of the first source electrode 173a and the first drain electrode 175a, which extend beyond the first semiconductor member 153a, may contact a side surface of the first semiconductor member 153a.

The second source electrode 173b may be electrically connected to the first data line 171-1, and in some embodiments, may be connected to the first source electrode 173a. The second source electrode 173b may be located on the second semiconductor member 153b, overlap with the second semiconductor member 153b, and be in contact with the second semiconductor member 153b. In some embodiments, a part of the second source electrode 173b, located on the second semiconductor member 153b, may have a U shape. In an embodiment, in some embodiments, the second source electrode 173b may have a shape symmetrical to that of the first source electrode 173a with respect to an axis which extends in the first direction.

The second drain electrode 175b may be located on the second semiconductor member 153b, overlap with the second semiconductor member 153b, and be in contact with the second semiconductor member 153b. The second drain electrode 175b is spaced apart from the second source electrode 173b on the second semiconductor member 153b. The second drain electrode 175b may include a bar-shaped part which faces the second source electrode 173b and stretches generally parallel to the second direction DR2, and an extension portion opposite thereto. The bar-shaped part of the second drain electrode 175b may stretch generally parallel to the second direction DR2 from the second semiconductor member 153b toward the second subpixel area PA2. In an embodiment, the bar-shaped part of the second drain electrode 175b may extend beyond the second semiconductor member 153b.

In some embodiments, parts of the second source electrode 173b and the second drain electrode 175b, which extend beyond the second semiconductor member 153b, may come into contact with a side surface of the second semiconductor member 153b.

The third source electrode 173c may be electrically connected to the voltage division reference line 177. The third source electrode 173c may be located on the third semiconductor member 153c, overlap with the third semiconductor member 153c, and be in contact with the third semiconductor member 153c. In some embodiments, the third source electrode 173c may be a part of the voltage division reference line 177. That is, the third source electrode 173c may be formed to have a strip shape which extends in the second direction DR2 and may cross the third semiconductor member 153c.

The third drain electrode 175c may be located on the third semiconductor member 153c, overlap with the third semiconductor member 153c, and be in contact with the third semiconductor member 153c. The third drain electrode 175c is spaced apart from the third source electrode 173c on the third semiconductor member 153c. The third drain electrode 175c may include a bar-shaped part which faces the third source electrode 173c and stretches generally parallel to the second direction DR2, and may be connected to the second drain electrode 175b. The bar-shaped part of the third drain electrode 175c may stretch generally parallel to the second direction DR2 from the third semiconductor member 153c toward the second subpixel area PA2. In an embodiment, the bar-shaped part of the third drain electrode 175c may extend beyond the third semiconductor member 153c.

The second conductive layer 170 may include one or more of Mo, Al, Pt, Pd, Ag, Mg, Au, Ni, Nd, Ir, Cr, Ti, Ta, W, and Cu. In an embodiment, the second conductive layer 170 may have a single-layer structure or a multilayer structure. For example, the second conductive layer 170 may be formed in a deposition structure such as one of Ti/Al/Ti, Mo/Al/Mo, Mo/AlGe/Mo, Ti/Cu, and the like.

The first gate electrode 124a, the first semiconductor member 153a, the first source electrode 173a, and the first drain electrode 175a may form the first switching element T1 which is a thin film transistor. The second gate electrode 124b, the second semiconductor member 153b, the second source electrode 173b, and the second drain electrode 175b may form the second switching element T2 which is a thin film transistor. In an embodiment, the third gate electrode 124c, the third semiconductor member 153c, the third source electrode 173c, and the third drain electrode 175c may form the third switching element T3 which is a thin film transistor.

An organic layer 180 may be disposed on the second conductive layer 170. The organic layer 180 may include a photosensitive material having excellent planarization characteristics.

A color filter 160 may be located between the second conductive layer 170 and the organic layer 180. The color of the color filter 160 may be any one of red, green, and blue but is not limited thereto. As shown in FIGS. 4 and 5, the color filter 160 may be adjacent to a color filter 1601 of a pixel adjacent to one side and a color filter 1602 of a pixel adjacent to the other side. The color filter 160 may be located in the first subpixel area PA1 and the second subpixel area PA2 to overlap with the first subpixel electrode 191 and the second subpixel electrode 192. In an embodiment, in some embodiments, the color filter 160 may be further disposed in the switching element area TA to overlap with the first switching element T1, the second switching element T2, and the third switching element T3.

When the display device 1 includes the color filter 160, the organic layer 180 may be disposed on the color filter 160 and may planarize unevenness of the color filter 160. In an embodiment, at least one of the organic layer 180 and the color filter 160 may be unnecessary. In an embodiment, the display device 1 includes the organic layer 180 and the color filter 160.

A first contact hole CH1 which exposes a part of the first drain electrode 175a and a second contact hole CH2 which exposes a part of the second drain electrode 175b may be formed at the color filter 160 and the organic layer 180. In some embodiments, the part exposed through the first contact hole CH1 may be the extension portion of the first drain electrode 175a, and the part exposed through the second contact hole CH2 may be the extension portion of the second drain electrode 175b.

A third conductive layer 190 may be located above the organic layer 180.

The third conductive layer 190 includes the first subpixel electrode 191 and the second subpixel electrode 192.

The first subpixel electrode 191 may be mostly located in the first subpixel area PA1, and the second subpixel electrode 192 may be mostly located in the second subpixel area PA2.

The first subpixel electrode 191 may be electrically connected to the first drain electrode 175a through the first contact hole CH1. In some embodiments, the first subpixel electrode 191 may come into contact with the first drain electrode 175a. The second subpixel electrode 192 may be electrically connected to the second drain electrode 175b through the second contact hole CH2, and in some embodiments, may come into contact with the second drain electrode 175b.

The first subpixel electrode 191 may include a first stem portion 191a located in the first subpixel area PA1, first branch portions 191b protruding from the first stem portion 191a and spaced by slits 191c in the first subpixel area PA1, and a first extension portion 191d which extends from the first subpixel area PA1 toward the switching element area TA.

The first stem portion 191a may include a lateral stem portion which stretches generally in the first direction DR1 and a longitudinal stem portion which stretches generally in the second direction DR2, and the first stem portion 191a may divide a pixel electrode PE into a plurality of subareas, that is, a plurality of domains. In some embodiments, the first stem portion 191a may be provided in a cross shape. In this case, the first subpixel electrode 191 may be divided by the first stem portion 191a into four subareas, that is, four domains. The first branch portions 191b located in the subareas may stretch in different directions. For example, in FIG. 2, the first branch portion 191b located in a rightward-upward subarea may stretch rightward-upward from the first stem portion 191a, and the first branch portion 191b located in a rightward-downward subarea may stretch rightward-downward from the first stem portion 191a. In an embodiment, the first branch portion 191b located in a leftward-upward subarea may stretch leftward-upward from the first stem portion 191a, and the first branch portion 191b located in a leftward-downward subarea may stretch leftward-downward from the first stem portion 191a.

The first extension portion 191d extends from the first stem portion 191a or the first branch portion 191b toward the switching element area TA and comes into contact with the first drain electrode 175a through the first contact hole CH1.

Like the first subpixel electrode 191, the second subpixel electrode 192 may include a second stem portion 192a located in the second subpixel area PA2, second branch portions 192b protruding from the second stem portion 192a and spaced by slits 192c in the first subpixel area PA1, and a second extension portion 192d which extends from the second subpixel area PA2 toward the switching element area TA.

Since descriptions of the second stem portion 192a, the second branch portions 192b, and the second extension portion 192d are substantially identical or similar to those of the first stem portion 191a, the first branch portions 191b, and the first extension portion 191d, the descriptions thereof will be omitted.

The first subpixel electrode 191 may overlap with the first data line 171-1 and the second data line 171-2. Parts of the first data line 171-1 and the second data line 171-2, which are located in the first subpixel area PA1, may completely overlap with the first subpixel electrode 191. For example, an overlap width WO1 between the first data line 171-1 and the first subpixel electrode 191 in the first subpixel area PA1 may be substantially equal to a line width WD1 of the first data line 171-1, and an overlap width WO2 between the second data line 171-2 and the first subpixel electrode 191 in the first subpixel area PA1 may be substantially equal to a line width WD2 of the second data line 171-2.

Likewise, the second subpixel electrode 192 may overlap with the first data line 171-1 and the second data line 171-2. Parts of the first data line 171-1 and the second data line 171-2, which are located in the second subpixel area PA2, may completely overlap with the second subpixel electrode 192. For example, an overlap width WO3 of the first data line 171-1 and the second subpixel electrode 192 in the second subpixel area PA2 may be substantially equal to the line width WD1 of the first data line 171-1, and an overlap width WO4 of the second data line 171-2 and the second subpixel electrode 192 in the second subpixel area PA2 may be substantially equal to the line width WD2 of the second data line 171-2.

In an embodiment, the first conductive layer 120 may further include a first maintenance line 127 and a second maintenance line 128. In some embodiments, a maintenance voltage may be applied to the first maintenance line 127 and the second maintenance line 128 and may be identical to the common voltage applied to the common electrode 270 but is not limited thereto. In some embodiments, the maintenance voltage may have a different level from that of the voltage applied to the voltage division reference line 177.

The first maintenance line 127 and the second maintenance line 128 may include the same material as that of the gate line 121 and may be located on the same layer.

The first maintenance line 127 may include a first portion 1271 which stretches in the first direction DR1 substantially like that of the gate line 121, a second portion 1273 which extends from the first portion 1271 in the second direction DR2 and is disposed adjacent to one side of the first subpixel electrode 191 (for example, a left side in the drawing), a third portion 1275 which extends from the first portion 1271 in the second direction DR2 and is disposed adjacent to the other side of the first subpixel electrode 191 (for example, a right side in the drawing), and a fourth portion 1277 which protrudes from the first portion 1271.

In some embodiments, the second portion 1273 and the third portion 1275 may not overlap with the first subpixel electrode 191. The second portion 1273 and the third portion 1275 may function as light shielding members which prevent light transmission on both sides of the first subpixel electrode 191.

In some embodiments, the fourth portion 1277 may partially overlap with the first subpixel electrode 191 to form maintenance capacitance in the first subpixel area PA1.

Like the first maintenance line 127, the second maintenance line 128 may include a fifth portion 1281 which stretches in the first direction DR1 substantially like that of the gate line 121, a sixth portion 1283 which extends from the fifth portion 1281 in the second direction DR2 and is disposed adjacent to one side of the second subpixel electrode 192 (for example, a left side in the drawing), a seventh portion 1285 which extends from the fifth portion 1281 in the second direction DR2 and is disposed adjacent to the other side of the second subpixel electrode 192 (for example, a right side in the drawing), and an eighth portion 1287 which protrudes from the fifth portion 1281.

In some embodiments, the sixth portion 1283 and the seventh portion 1285 may not overlap with the second subpixel electrode 192. The sixth portion 1283 and the seventh portion 1285 may function as light shielding members which prevent light transmission on both sides of the second subpixel electrode 192.

In some embodiments, the eighth portion 1287 may partially overlap with the second subpixel electrode 192 to form maintenance capacitance in the second subpixel area PA2.

In an embodiment, the third conductive layer 190 may further include a first shielding electrode SHE1, a second shielding electrode SHE2, and a connection electrode SHEc. The first shielding electrode SHE1, the second shielding electrode SHE2, and the connection electrode SHEc may be located on the same layer as that of the first subpixel electrode 191 and the second subpixel electrode 192 and may include the same material as that of the first subpixel electrode 191 and the second subpixel electrode 192.

The first shielding electrode SHE1, the second shielding electrode SHE2, and the connection electrode SHEc may be physically spaced apart from the first subpixel electrode 191 and the second subpixel electrode 192.

The first shielding electrode SHE1 may be located on the organic layer 180 and may overlap with the second portion 1273 of the first maintenance line 127 and the sixth portion 1283 of the second maintenance line 128.

The second shielding electrode SHE2 may be located on the organic layer 180 and may overlap with the third portion 1275 of the first maintenance line 127 and the seventh portion 1285 of the second maintenance line 128.

In some embodiments, in a plan view, the first shielding electrode SHE1 may completely cover the second portion 1273 of the first maintenance line 127 and the sixth portion 1283 of the second maintenance line 128. In an embodiment, a line width of the first shielding electrode SHE1 or a width WS1 thereof in the first direction DR1 may be greater than a line width WC1 of the second portion 1273 and a line width WC3 of the fifth portion 1281. Likewise, in a plane view, the second shielding electrode SHE2 may completely cover the third portion 1275 of the first maintenance line 127 and the seventh portion 1285 of the second maintenance line 128. In an embodiment, a line width of the second shielding electrode SHE2 or a width WS2 thereof in the first direction DR1 may be greater than a line width WC2 of the third portion 1275 and a line width WC4 of the sixth portion 1283.

The connection electrode SHEc may electrically connect the first shielding electrode SHE1 to the second shielding electrode SHE2.

A voltage at the same level as that of the common voltage applied to the common electrode 270 may be applied to the first shielding electrode SHE1 and the second shielding electrode SHE2. Accordingly, an electric field may not be formed between the common electrode 270 and the first shielding electrode SHE1 and between the common electrode 270 and the second shielding electrode SHE2. Accordingly, a possibility of misalignment of liquid crystal molecules located on both sides of the first subpixel electrode 191 and the second subpixel electrode 192 may be decreased and a light leakage may be reduced. In an embodiment, an area of a light shielding member 220 formed to prevent the light leakage may be more reduced or may be omitted. Accordingly, an opening rate of the display device 1 may be more increased.

The second substrate 200 may have the following structures.

The second substrate 200 may include a second base substrate 210, the light shielding member 220, an overcoat layer 250, and the common electrode 270.

The second base substrate 210 may be an insulation substrate like the first base substrate 110. In an embodiment, the second base substrate 210 may include polymers or plastic having high heat resistance. In some embodiments, the second base substrate 210 may have flexibility.

The light shielding member 220 may be located on one surface of the second base substrate 210, which faces the first base substrate 110. In some embodiments, the light shielding member 220 may overlap with the switching element area TA. The light shielding member 220 may include a light shielding pigment such as black carbon or an opaque material such as Cr and may include a photosensitive organic material. In an embodiment, the light shielding member 220 may be located on the first substrate 100.

The overcoat layer 250 may be formed on one surface of the second base substrate 210 and may cover the light shielding member 220. The overcoat layer 250 may planarize unevenness formed by the light shielding member 220. In some embodiment, the overcoat layer 250 may be omitted.

The common electrode 270 may be located on the overcoat layer 250. In some embodiments, when the overcoat layer 250 is omitted, the common electrode 270 may be located above the second base substrate 210 and the light shielding member 220. The common electrode 270 may include a transparent conducting material such as an indium tin oxide (ITO), indium zinc oxide (IZO), and the like. In some embodiments, the common electrode 270 may be formed overall throughout the entire surface of the second base substrate 210. The common voltage is applied to the common electrode 270 to form an electric field with the first subpixel electrode 191 and the second subpixel electrode 192, and alignment of the liquid crystal molecules in the liquid crystal layer 300 is changed according to a size of the electric field such that light transmittance may be controlled.

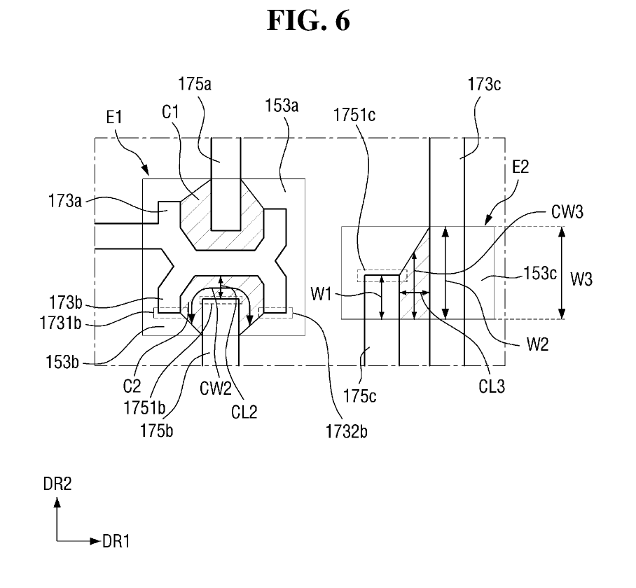

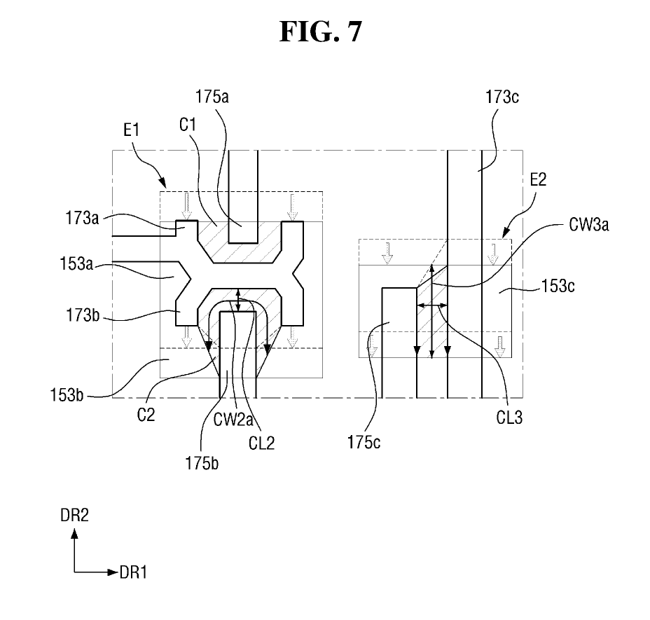

FIG. 6 is an enlarged view of part Q1 of FIG. 2, which illustrates structures of the first semiconductor member, the first source electrode, the first drain electrode, the second semiconductor member, the second source electrode, the second drain electrode, the third semiconductor member, the third source electrode, and the third drain electrode according to one embodiment. FIG. 7 is an enlarged view of part Q1 of FIG. 2 according to one embodiment. Structures related to the first semiconductor member, the second semiconductor member, and the third semiconductor member may be different in FIG. 6 and FIG. 7.

Referring to FIGS. 6 and 7 in addition to FIGS. 1 to 5, the first semiconductor member 153a includes a first channel area C1 defined to be an area between the first source electrode 173a and the first drain electrode 175a. The channel area refers to a region in which a channel is formed by inverting a conductivity type between a source electrode and a drain electrode if an electrical field is applied by a gate electrode (not shown) that at least partially overlaps with the channel area. As described above, the channel area may be defined as a region of a semiconductor member between the source electrode and the drain electrode.

Likewise, the second semiconductor member 153b includes a second channel area C2 defined to be an area between the second source electrode 173b and the second drain electrode 175b.

In some embodiments, the second source electrode 173b, as described above, may be formed in a U shape and may include two ends 1731a and 1731b. The two ends 1731a and 1731b of the second source electrode 173b may be located inside an edge E1 of the first semiconductor member 153a and the second semiconductor member 153b and may overlap with the second semiconductor member 153b. In an embodiment, the end may not extend beyond a semiconductor member and may terminate on the semiconductor member.

The second drain electrode 175b, as described above, may extend beyond the second semiconductor member 153b in the second direction DR2 and may have a bar shape which extends downward or toward the second subpixel area PA2 in the drawing. One end 1751b of the second drain electrode 175b may be located inside the edge E1 of the first semiconductor member 153a and the second semiconductor member 153b and may overlap with the second semiconductor member 153b.

In the second semiconductor member 153b, the above-described second channel area C2 is defined between the second source electrode 173b and the second drain electrode 175b.

The second channel area C2 may have a first channel length CL2 and a first channel width CW2. The first channel length CL2 may be defined to be a distance between the second source electrode 173b and the second drain electrode 175b on the second semiconductor member 153b. The first channel width CW2 may be a distance defined in a direction perpendicular to the first channel length CL2. In some embodiments, the first channel width CW2 may be defined to be a distance measured along intermediate dots between the second source electrode 173b and the second drain electrode 175b, which overlap with the second semiconductor member 153b.

The third semiconductor member 153c includes a third channel area C3 defined to be an area between the third source electrode 173c and the third drain electrode 175c.

In some embodiments, as described above, the third source electrode 173c may be a part of the voltage division reference line 177. Accordingly, the third source electrode 173c may extend in the second direction DR2 substantially parallel to the second drain electrode 175b and may cross the third semiconductor member 153c without an end which overlaps with the third semiconductor member 153c. In other words, an end of the third source electrode 173c may not be located inside an edge E2 of the third semiconductor member 153c and accordingly may not overlap with the third semiconductor member 153c.

The third drain electrode 175c may extend beyond the third semiconductor member 153c in the second direction DR2 substantially parallel to the second drain electrode 175b and may have a bar shape which extends downward in the drawing. One end 1751c of the third drain electrode 175c may be located inside the edge E2 of the third semiconductor member 153c and may overlap with the third semiconductor member 153c.

A first overlap width W1 of the third drain electrode 175c and the third semiconductor member 153c, which is measured in the second direction DR2 in which the second drain electrode 175b extends may be different from a second overlap width W2 of the third source electrode 173c and the third semiconductor member 153c, which is measured in the second direction DR2. That is, on the third semiconductor member 153c, the third source electrode 173c and the third drain electrode 175c may not be symmetrical to each other with respect to an axis which extends in the second direction DR2. In embodiments, an overlap width refers to a width of a maximum overlap between two components.

As described above, the one end 1751c of the third drain electrode 175c may overlap with the third semiconductor member 153c. In an embodiment, an end of the third source electrode 173c may not overlap with the third semiconductor member 153c and may cross the third semiconductor member 153c in the second direction DR2. Accordingly, a width W3 of the third semiconductor member 153c, which is measured in the second direction DR2, may be greater than the first overlap width W1 of the third drain electrode 175c and the third semiconductor member 153c and may be substantially equal to the second overlap width W2 of the third source electrode 173c and the third semiconductor member 153c.

In the third semiconductor member 153c, the above-described third channel area C3 is defined between the third source electrode 173c and the third drain electrode 175c.

The third channel area C3 may have a second channel length CL3 and a second channel width CW3. The second channel length CL3 may be defined to be a distance between the third source electrode 173c and the third drain electrode 175c on the third semiconductor member 153c. The second channel width CW3 may be a distance defined in a direction perpendicular to the second channel length CL3. In some embodiments, the second channel width CW3 may be defined to be a distance measured along intermediate dots between the third source electrode 173c and the third drain electrode 175c, which overlap with the third semiconductor member 153c.

Although a data voltage which passes through the first switching element T1 is applied to the first subpixel electrode 191 through the first drain electrode 175a, a data voltage which passes through the second switching element T2 is partially output through the second drain electrode 175b and applied to the second subpixel electrode 192 due to the third switching element T3. Accordingly, brightness of the first subpixel area PA1 in which the first subpixel electrode 191 is located is higher than brightness of the second subpixel area PA2 in which the second subpixel electrode 192 is located.

A data voltage is divided according to a resistance ratio between the second switching element T2 and the third switching element T3. The resistance ratio relates to an aspect ratio which is a significant feature of a switching element such as a thin film transistor (TFT). In an embodiment, the aspect ratio refers to a ratio of a channel width to a channel length.

For example, when it is assumed that the data voltage applied to the first subpixel electrode 191 through the first drain electrode 175a is V1 and the data voltage applied to the second subpixel electrode 192 through the second drain electrode 175b is V2, they have a following relationship. A ratio of V2 to V1, that is, V2/V1 may be calculated by (CW2/CL2)/{(CW2/CL2)+(CW3/CL2)}. The ratio V2/V1 may be referred to as a voltage ratio.

Since the second conductive layer 170 and the semiconductor layer 150 are formed using different masks as described above, alignment between the second conductive layer 170 and the semiconductor layer 150 may change during a manufacturing process. In an embodiment, when the display device 1 has a large size, alignment between the second conductive layer 170 and the semiconductor layer 150 may be different for each area of the display device 1.

When the first semiconductor member 153a, the second semiconductor member 153b, and the third semiconductor member 153c are shifted in the first direction DR1, for example, shifted leftward or rightward with respect to FIG. 6, the first channel length CL2 and the first channel width CW2 of the second channel area C2 do not substantially change. In an embodiment, since the second channel length CL3 and the second channel width CW3 of the third channel area C3 do not substantially change, the voltage ratio (V2/V1) does not change. This is because the first direction DR1 in which the first semiconductor member 153a, the second semiconductor member 153b, and the third semiconductor member 153c are shifted is different from the second direction DR2 in which the second drain electrode 175b, the third drain electrode 175c, and the third source electrode 173c extend.

On the other hand, as shown in FIG. 7, when it is assumed that the first semiconductor member 153a, the second semiconductor member 153b, and the third semiconductor member 153c are shifted downward in the second direction DR2 with respect to the drawing, a data voltage output from the first semiconductor member 153a does not substantially change.

In an embodiment, in the case of the shifted second semiconductor member 153b, the first channel length CL2 of the second channel area C2 does not substantially change or a range of change thereof may be minuscule. On the other hand, since a first channel width CW2a of the second channel area C2 increases in comparison with the first channel width CW2 before being shifted and a part of the second semiconductor member 153b is shifted, an aspect ratio of the second channel area C2 changes from CW2/CL2 into CW2a/CL2. Accordingly, when the aspect ratio of the second channel area C2 changes and an aspect ratio of the third channel area C3 is constantly maintained, a ratio (V2/V1) of the data voltage output through the second drain electrode 175b to the data voltage output through the first drain electrode 175a may change and accordingly there is a possibility in which display quality of the display device 1 may not be uniform for each area. That is, since a possibility in which the second drain electrode 175b extends in the second direction DR2 toward the second subpixel area PA2 is high, when the second semiconductor member 153b is shifted in the second direction DR2, a possibility in which display quality and visibility are not uniform for each area in the display device 1 is high.

On the other hand, when the second semiconductor member 153b is shifted, the third semiconductor member 153c formed using the same mask as that of the second semiconductor member 153b is also shifted. In the case of the shifted third semiconductor member 153c, the second channel length CL3 of the third channel area C3 does not substantially change or a range of change thereof may be minuscule. In an embodiment, a second channel width CW3a of the third channel area C3 increases in comparison with the second channel width CW3 before being shifted.

In an embodiment, although not shown in the drawings, when it is assumed that the first semiconductor member 153a, the second semiconductor member 153b, and the third semiconductor member 153c are shifted upward with respect to the drawing, the first channel width CW2 of the second channel area C2 and the second channel width CW3 of the second channel area C2 are reduced together.

That is, when the second semiconductor member 153b is shifted in the second direction DR2, the third semiconductor member 153c is also shifted in the second direction DR2. In an embodiment, since at least one of the third drain electrode 175c and the third source electrode 173c includes a part substantially parallel to the second drain electrode 175b and the end of the third drain electrode 175c is disposed to overlap with the third semiconductor member 153c, when the first channel width CW2 of the second channel area C2 increases, the second channel width CW3 of the third channel area C3 also increases and when the first channel width CW2 of the second channel area C2 decreases, the second channel width CW3 of the third channel area C3 also decreases. That is, the aspect ratio of the third channel area C3 increases or decreases according to an increase or decrease of the aspect ratio of the second channel area C2. Accordingly, even when the alignment between the second conductive layer 170 and the semiconductor layer 150 changes due to a processing margin during a manufacturing process, the voltage ratio (V2/V1) does not substantially change and may be maintained substantially uniform.

According to embodiments, display quality and visibility of the display device 1 may be maintained substantially uniform.

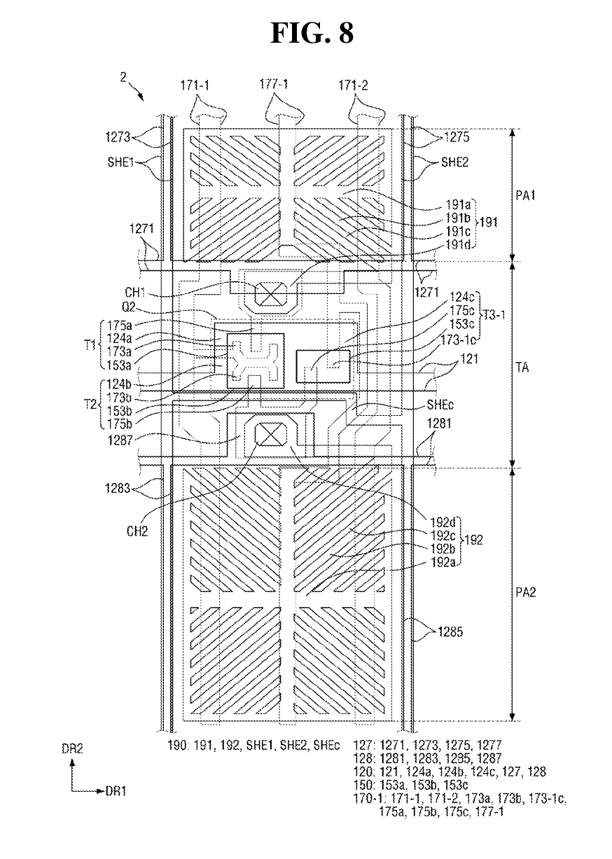

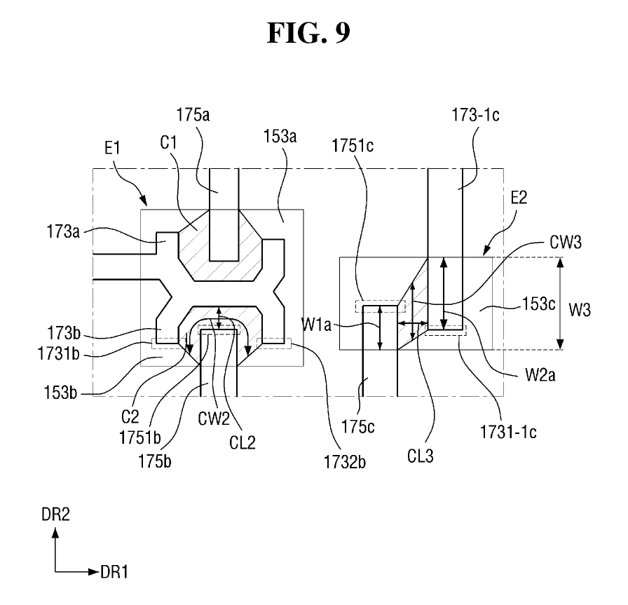

FIG. 8 is a layout view of one pixel of a display device according to one embodiment. FIG. 9 is an enlarged view of part Q2 of FIG. 8, which illustrates structures of a first semiconductor member, a first source electrode, a first drain electrode, a second semiconductor member, a second source electrode, a second drain electrode, a third semiconductor member, a third source electrode, and a third drain electrode according to one embodiment.

Referring to FIGS. 8 and 9, a display device 2 includes a second conductive layer 170-1 with components identical to, analogous to, or different from those of the display device 1 described above with reference to FIGS. 2 to 7. Description of previously-described parts may not be repeated, and different parts are described.

A voltage division reference line 177-1 included in the second conductive layer 170-1 does not overlap with the third semiconductor member 153c. In an embodiment, a third source electrode 173-1c of a third switching element T3-1 extends from the voltage division reference line 177-1 and overlaps with the third semiconductor member 153c. Some other components of the second conductive layer 170-1 may be identical to or analogous to some components of the second conductive layer 170 described above with reference to FIGS. 2 to 7.

The third source electrode 173-1c may extend beyond the third semiconductor member 153c in the second direction DR2 substantially parallel to the second drain electrode 175b and may have a bar shape which extends upward from the third semiconductor member 153c toward the first subpixel area PA1 in the drawing. One end 1731-1c of the third source electrode 173-1c may be located inside the edge E2 of the third semiconductor member 153c and may overlap with the third semiconductor member 153c.

As described above, the one end 1751c of the third drain electrode 175c may overlap with the third semiconductor member 153c. In an embodiment, the one end 1731-1c of the third source electrode 173-1c may also overlap with the third semiconductor member 153c. Accordingly, the width W3 of the third semiconductor member 153c, which is measured in the second direction DR2, may be greater than a first overlap width W1a of the third drain electrode 175c and the third semiconductor member 153c and may be greater than a second overlap width W2a of the third source electrode 173-1c and the third semiconductor member 153c.

A relationship between the first overlap width W1a and the second overlap width W2a may be variable. For example, the first overlap width W1a and the second overlap width W2a may be substantially equal. In an embodiment, the first overlap width W1a may be greater than the second overlap width W2a. On the other hand, the second overlap width W2a may be greater than the first overlap width W1a. Regardless of sizes of the first overlap width W1a and the second overlap width W2a, the third source electrode 173-1c and the third drain electrode 175c may not be symmetrical to each other with respect to an axis which extends in the second direction DR2 on the third semiconductor member 153c.

In the display device 2, when the first channel width CW2 of the second channel area C2 increases, the second channel width CW3 of the third channel area C3 also increases. When the first channel width CW2 of the second channel area C2 decreases, the second channel width CW3 of the third channel area C3 also decreases. Accordingly, even when alignment between the second conductive layer 170-1 and the semiconductor layer 150 changes in a manufacturing process, display quality and visibility of the display device 2 may be maintained substantially uniform.

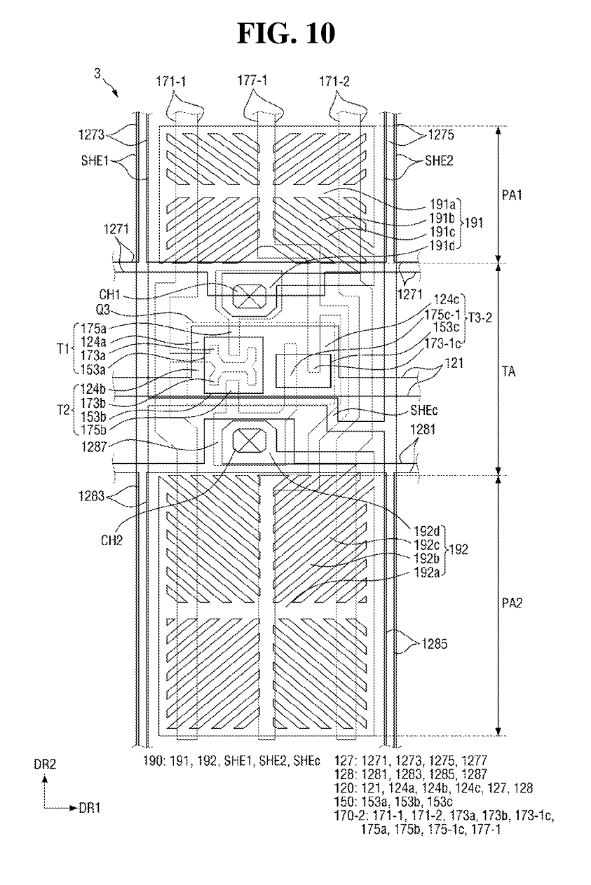

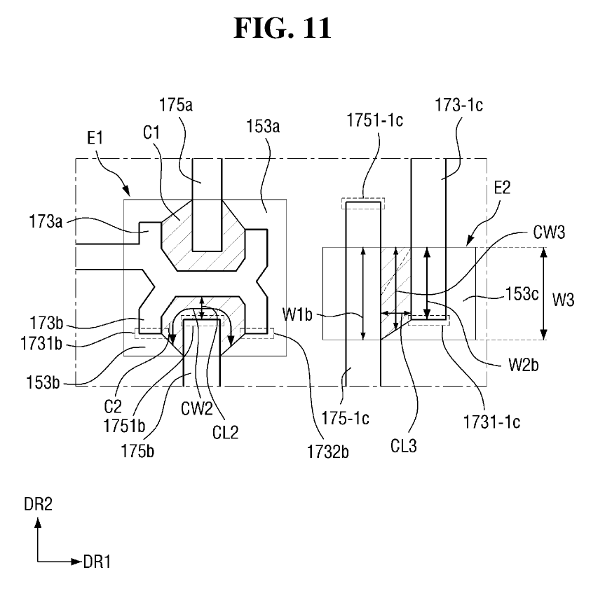

FIG. 10 is a layout view of one pixel of a display device according to one embodiment. FIG. 11 is an enlarged view of part Q3 of FIG. 10, which illustrates structures of a first semiconductor member, a first source electrode, a first drain electrode, a second semiconductor member, a second source electrode, a second drain electrode, a third semiconductor member, a third source electrode, and a third drain electrode.

Referring to FIGS. 10 and 11, a display device 3 according to one embodiment includes a second conductive layer 170-2 with components different from those of the display device 2 described above with reference to FIGS. 8 and 9, and other components thereof are substantially identical. Accordingly, repetitive parts will be omitted and differences will be mainly described.

A third drain electrode 175-1c of a third switching element T3-2 included in the second conductive layer 170-2 may include an end 1751-1c not located in the edge E2 of the third semiconductor member 153c and not overlapping with the third semiconductor member 153c. That is, the third drain electrode 175-1c may cross the third semiconductor member 153c in the second direction DR2. Other components may be substantially identical to those of the second conductive layer 170-1 described above with reference to FIGS. 8 and 9.

Since the third drain electrode 175-1c is disposed across the third semiconductor member 153c and the end 1731-1c of the third source electrode 173-1c overlaps with the third semiconductor member 153c, a first overlap width W1b of the third drain electrode 175-1c and the third semiconductor member 153c, which is measured in the second direction DR2, may be greater than a second overlap width W2b of the third source electrode 173-1c and the third semiconductor member 153c, which is measured in the second direction DR2.

In an embodiment, the width W3 of the third semiconductor member 153c, which is measured in the second direction DR2, may be substantially equal to the first overlap width W1b and may be greater than the second overlap width W2b. In an embodiment, on the third semiconductor member 153c, the third source electrode 173-1c and the third drain electrode 175-1c may not be symmetrical to each other with respect to an axis which extends in the second direction DR2.

In the display device 3, since the first channel width CW2 of the second channel area C2 and the second channel width CW3 of the third channel area C3 increase or decrease together, even when alignment between the second conductive layer 170-2 and the semiconductor layer 150 changes during a manufacturing process, display quality and visibility of the display device 3 may be maintained substantially uniform.

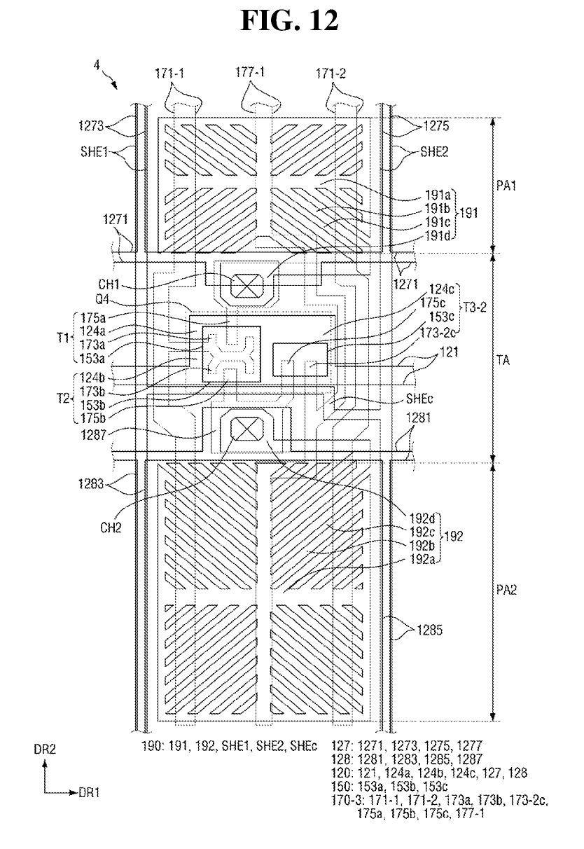

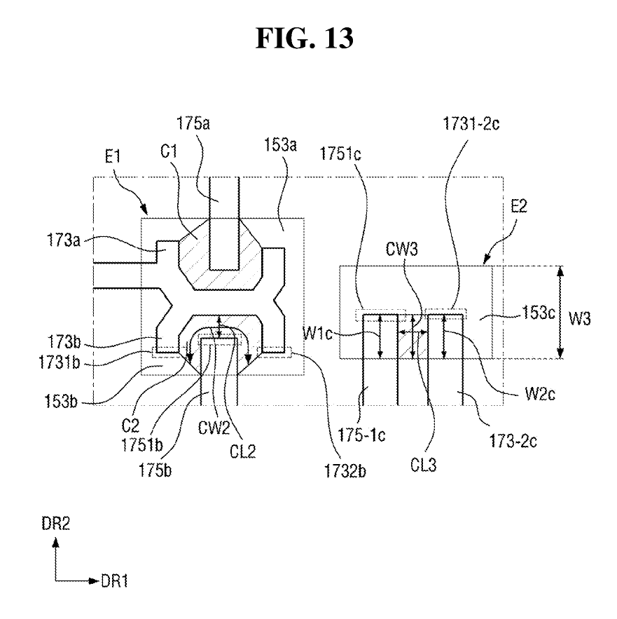

FIG. 12 is a layout view of one pixel of a display device according to one embodiment, and FIG. 13 is an enlarged view of part Q4 of FIG. 12, which illustrates structures of a first semiconductor member, a first source electrode, a first drain electrode, a second semiconductor member, a second source electrode, a second drain electrode, a third semiconductor member, a third source electrode, and a third drain electrode.

Referring to FIGS. 12 and 13, a display device 4 according to one embodiment includes a second conductive layer 170-3 with components different from those of the display device 2 described above with reference to FIGS. 8 and 9, and other components thereof are substantially identical. Accordingly, repetitive parts will be omitted and differences will be mainly described.

A third source electrode 173-2c of a third switching element T3-3 included in the second conductive layer 170-3 may extend beyond the third semiconductor member 153c in the second direction DR2 substantially parallel to the second drain electrode 175b and may have a bar shape which extends downward from the third semiconductor member 153c toward the second subpixel area PA2 in the drawing. One end 1731-2c of the third source electrode 173-2c may be located inside the edge E2 of the third semiconductor member 153c and may overlap with the third semiconductor member 153c.

As described above, the one end 1751c of the third drain electrode 175c may overlap with the third semiconductor member 153c. In an embodiment, the one end 1731-2c of the third source electrode 173-2c may also overlap with the third semiconductor member 153c. Accordingly, the width W3 of the third semiconductor member 153c, which is measured in the second direction DR2, may be greater than a second overlap width W2c of the third source electrode 173-2c and the third semiconductor member 153c and may be substantially equal to a first overlap width W1c of the third drain electrode 175c and the third semiconductor member 153c.

A relationship between the first overlap width W1c and the second overlap width W2c may be variable. For example, the first overlap width W1c and the second overlap width W2c may be substantially equal. In an embodiment, the first overlap width W1c may be greater than the second overlap width W2c. On the other hand, the second overlap width W2c may be greater than the first overlap width W1c.

When the first overlap width W1c and the second overlap width W2c are substantially equal to each other, the third source electrode 173-2c and the third drain electrode 175c may be symmetrical to each other with respect to an axis which extends in the second direction DR2 but are not limited thereto.

In an embodiment, when the first overlap width W1c and the second overlap width W2c are unequal to each other, the third source electrode 173-2c and the third drain electrode 175c may be asymmetrical to each other with respect to an axis which extends in the second direction DR2.

In the display device 4, when the first channel width CW2 of the second channel area C2 increases, the second channel width CW3 of the third channel area C3 also increases. When the first channel width CW2 of the second channel area C2 decreases, the second channel width CW3 of the third channel area C3 also decreases. Accordingly, even when alignment between the second conductive layer 170-3 and the semiconductor layer 150 changes in a manufacturing process, display quality and visibility of the display device 4 may be maintained substantially uniform.

According to embodiments, a display device may have uniform display quality.

Although example embodiments have been described, various modifications and applications may be made to implement other embodiments. All the embodiments, modifications, and applications are within the scope defined by the attached claims.

What is claimed is:

1. A display device comprising:
a base substrate;
a gate line located on the base substrate;
a first data line electrically insulated from the gate line and intersecting the gate line;
a voltage division reference line electrically insulated from each of the gate line and the first data line;
a first switching element which comprises a first gate electrode electrically connected to the gate line, a first semiconductor member overlapping the first gate electrode, a first source electrode electrically connected to the first data line and overlapping the first semiconductor member, and a first drain electrode overlapping the first semiconductor member and spaced from the first source electrode;
a second switching element which comprises a second gate electrode electrically connected to the gate line, a second semiconductor member overlapping the second gate electrode, a second source electrode electrically connected to the first data line and overlapping the second semiconductor member, and a second drain electrode overlapping the second semiconductor member and extending beyond the second semiconductor member in a first direction;
a third switching element which comprises a third gate electrode electrically connected to the gate line, a third semiconductor member overlapping the third gate electrode, a third source electrode electrically connected to the voltage division reference line and overlapping the third semiconductor member, and a third drain electrode overlapping the third semiconductor member and electrically connected to the second drain electrode;
a first subpixel electrode electrically connected to the first drain electrode; and
a second subpixel electrode electrically connected to the second drain electrode,
wherein a first overlap width is in the first direction and is a width of a maximum portion of the third drain electrode positioned within a perimeter of the third semiconductor member in a plan view of the display device,
wherein a second overlap width is in the first direction and is a width of a maximum portion of the third source electrode positioned within the perimeter of the third semiconductor member in the plan view of the display device,
wherein the first overlap width is unequal to the second overlap width.

2. The display device of claim 1, wherein the second subpixel electrode is spaced from the second semiconductor member in the first direction in the plan view of the display device.

3. The display device of claim 2, wherein a width of the third semiconductor member in the first direction is greater than the first overlap width and substantially equal to the second overlap width.

4. The display device of claim 2, wherein a width of the third semiconductor member in the first direction is greater than the second overlap width and substantially equal to the first overlap width.

5. The display device of claim 2, wherein a width of the third semiconductor member in the first direction is greater than each of the first overlap width and the second overlap width.

6. The display device of claim 1, wherein a side of the third semiconductor member directly contacts each of the third source electrode and the third drain electrode.

7. The display device of claim 1, wherein exactly one of an end of the third source electrode and an end of the third drain electrode is located inside the perimeter of the third semiconductor member in the plan view of the display device.

8. The display device of claim 1, wherein a portion of the voltage division reference line extends in the first direction and overlaps both the first subpixel electrode and the second subpixel electrode.

9. The display device of claim 8, wherein the voltage division reference line and the first data line directly contact a same side of a same component and comprise a same material.

10. The display device of claim 1, further comprising a gate insulting layer located between the first data line and the gate line,
wherein the first data line directly contacts the gate insulating layer.

11. The display device of claim 10, wherein the first data line extends in the first direction and overlaps both the first subpixel electrode and the second subpixel electrode.

12. The display device of claim 11, wherein two edges of the first data line are positioned between two edges of the first subpixel electrode in the plan view of the display device.

13. The display device of claim 11, further comprising a second data line which extends in the first direction and overlaps both the first subpixel electrode and the second subpixel electrode,
wherein two edges of the second data line are positioned between the two edges of the first subpixel electrode in the plan view of the display device.

14. The display device of claim 1, further comprising a first maintenance line, wherein a first portion of the first maintenance line extends parallel to the gate line, wherein a second portion of the first maintenance line extends from the first portion and extends parallel to the first data line, wherein a third portion of the first maintenance line extends from the first portion and extends parallel to the first data line, wherein a component of the display device directly contacts the first maintenance line without directly contacting the voltage division reference line, wherein the first data line overlaps the first subpixel electrode, and wherein the first subpixel electrode is positioned between the second portion of the first maintenance line and the third portion of the first maintenance line in the plan view of the display device.

15. The display device of claim 14, wherein the first maintenance line and the gate line directly contact a same side of a same component and comprise a same material.

16. The display device of claim 14, further comprising:
a first shielding electrode overlapping the second portion of the first maintenance line; and
a second shielding electrode overlapping the third portion of the first maintenance line,
wherein both the first subpixel electrode and the second subpixel electrode are positioned between the first shielding electrode and the second shielding electrode in the plan view of the display device, and
wherein the first shielding electrode, the second shielding electrode, and the first subpixel electrode directly contact a same side of a same component and comprise a same material.

17. The display device of claim 16, further comprising a second maintenance line spaced from the first maintenance line, wherein a first portion of the second maintenance line extends parallel to the gate line, wherein a second portion of the second maintenance line extends parallel to the first data line and is directly connected to the first portion of the second maintenance line, wherein a third portion of the second maintenance line extends parallel to the first data line and is directly connected to the first portion of the second maintenance line, wherein the second maintenance line and the first maintenance line directly contact a same side of a same layer, and wherein the second subpixel electrode is positioned between the second portion of the second maintenance line and the third portion of the second maintenance line in the plan view of the display device.

18. The display device of claim 17, wherein the second portion of the second maintenance line overlaps the first shielding electrode, and wherein the third portion of the second maintenance line overlaps the second shielding electrode.

19. A display device comprising:
a base substrate;
a gate line which is located on the base substrate and extends in a first direction;
a data line which is electrically insulated from the gate line and extends in a second direction different from the first direction;
a voltage division reference line electrically insulated from each of the gate line and the data line;
a first switching element which comprises a first gate electrode electrically connected to the gate line, a first semiconductor member overlapping the first gate electrode, a first source electrode electrically connected to the data line and overlapping the first semiconductor member, and a first drain electrode overlapping the first semiconductor member and spaced from the first source electrode;
a second switching element which comprises a second gate electrode electrically connected to the gate line, a second semiconductor member overlapping the second gate electrode, a second source electrode electrically connected to the data line and overlapping the second semiconductor member, and a second drain electrode overlapping the second semiconductor member and extending beyond the second semiconductor member in the second direction;
a third switching element which comprises a third gate electrode electrically connected to the gate line, a third semiconductor member overlapping the third gate electrode, a third source electrode electrically connected to the voltage division reference line and overlapping the third semiconductor member, and a third drain electrode overlapping the third semiconductor member, electrically connected to the second drain electrode, and extending beyond the third semiconductor member in the second direction;
a first subpixel electrode electrically connected to the first drain electrode; and
a second subpixel electrode electrically connected to the second drain electrode,
wherein a side of the third semiconductor member directly contacts the third drain electrode, and wherein an end of the third drain electrode overlaps the third semiconductor member and is located inside a perimeter of the third semiconductor member in a plan view of the display device.

20. A display device comprising:
a base substrate;
a gate line which is located on the base substrate and extends in a first direction;
a data line which is electrically insulated from the gate line and extends in a second direction different from the first direction;
a voltage division reference line electrically insulated from each of the gate line and the data line;
a first switching element which comprises a first gate electrode electrically connected to the gate line, a first semiconductor member overlapping the first gate electrode, a first source electrode electrically connected to the data line and overlapping the first semiconductor member, and a first drain electrode overlapping the first semiconductor member and spaced from the first source electrode;
a second switching element which comprises a second gate electrode electrically connected to the gate line, a second semiconductor member overlapping the second gate electrode, a second source electrode electrically connected to the data line and overlapping the second semiconductor member, and a second drain electrode overlapping the second semiconductor member and extending beyond the second semiconductor member in the second direction;
a third switching element which comprises a third gate electrode electrically connected to the gate line, a third semiconductor member overlapping the third gate electrode, a third source electrode electrically connected to the voltage division reference line, overlapping the third semiconductor member, and extending beyond the third semiconductor member in the second direction, and a third drain electrode overlapping the third semiconductor member and electrically connected to the second drain electrode;
a first subpixel electrode electrically connected to the first drain electrode; and
a second subpixel electrode electrically connected to the second drain electrode,
wherein a side of the third semiconductor member directly contacts the third source electrode, and wherein an end of the third source electrode overlaps the third semiconductor member and is located inside a perimeter of the third semiconductor member in a plan view of the display device.
